(19) United States
(12) Patent Application Publication
(10) Pub. No.: US 2016/0322507 A1
(43) Pub. Date: Nov. 3, 2016

(54) THIN FILM TRANSISTOR ARRAY PANEL AND METHOD OF MANUFACTURING THE SAME

(71) Applicant: SAMSUNG DISPLAY CO., LTD., Yongin-si (KR)

(72) Inventors: June Whan CHOI, Hwaseong-si (KR); Jun Hyuck JEON, Cheonan-si (KR); Seung-Kyeng CHO, Hwaseong-si (KR); Jang Soo KIM, Asan-si (KR); Jae Woo PARK, Seongnam-si (KR); Ki Seong SEO, Seoul (KR); Soo Woong LEE, Yongin-si (KR); Jeong Young LEE, Asan-si (KR)

(21) Appl. No.: 15/137,476

(22) Filed: Apr. 25, 2016

(30) Foreign Application Priority Data
Apr. 29, 2015 (KR) 10-2015-0060544

(51) Int. Cl. H01L 29/786; H01L 27/12; H01L 29/24

(52) U.S. Cl. CPC H01L 29/78606; H01L 29/7869; H01L 29/78696; H01L 29/24; H01L 27/1225; H01L 27/1262

(57) ABSTRACT

A thin film transistor array panel, including a substrate; a gate electrode on the substrate; a semiconductor layer on the substrate; a gate insulating layer between the gate electrode and the semiconductor layer, the gate insulating layer including a first oxide insulating layer in contact with the semiconductor layer; a source electrode on the semiconductor layer; a drain electrode facing the source electrode; and a passivation layer covering the source electrode and the drain electrode, the passivation layer including a second oxide insulating layer in contact with the source electrode and the drain electrode, at least one of the first oxide insulating layer and the second oxide insulating layer having a varying hydrogen content distribution in a thickness direction.

### CROSS-REFERENCE TO RELATED APPLICATION

Korean Patent Application No. 10-2015-0060544, filed on Apr. 29, 2015, in the Korean Intellectual Property Office, and entitled: “Thin Film Transistor Array Panel and Method of Manufacturing the Same,” is incorporated by reference herein in its entirety.

### BACKGROUND

1. Field

Embodiments relate to a thin film transistor array panel and a method of manufacturing the same.

2. Description of the Related Art

A display device, such as a liquid crystal display or an organic light emitting device, may include plural pairs of field generating electrodes and an electro-optical active layer interposed therebetween. The liquid crystal display may include a liquid crystal layer as an electro-optical active layer and the organic light emitting device may include an organic emission layer as an electro-optical active layer.

One of the field generating electrodes which may form a pair may be connected to a switching element to be applied with an electric signal and the electro-optical active layer may convert the electric signal into an optical signal to display an image.

### SUMMARY

Embodiments may be realized by providing a thin film transistor array panel, including a substrate; a gate electrode on the substrate; a semiconductor layer on the substrate; a gate insulating layer between the gate electrode and the semiconductor layer, the gate insulating layer including a first oxide insulating layer in contact with the semiconductor layer; a source electrode on the semiconductor layer; a drain electrode facing the source electrode; and a passivation layer covering the source electrode and the drain electrode, the passivation layer including a second oxide insulating layer in contact with the source electrode and the drain electrode, at least one of the first oxide insulating layer and the second oxide insulating layer having a varying hydrogen content distribution in a thickness direction.

A hydrogen content of at least one of the first oxide insulating layer and the second oxide insulating layer may be repeatedly increased and reduced in the thickness direction.

At least one of the first oxide insulating layer and the second oxide insulating layer may include a plurality of sub-insulating layers and a hydrogen content in each of the sub-insulating layers may be larger than a hydrogen content at an interface of the sub-insulating layers.

The hydrogen content in each of the sub-insulating layers may be maintained at a predetermined level.

A thickness of each of the sub-insulating layers may be 10 nm to 50 nm.

Five or more sub-insulating layers may be included in at least one of the first oxide insulating layer and the second oxide insulating layer.

A hydrogen content of the first oxide insulating layer may be smaller than a hydrogen content of the second oxide insulating layer.

The thin film transistor array panel may further include a barrier layer below the source electrode and the drain electrode. The barrier layer may include metal oxide.

The barrier layer may include indium-zinc oxide (IZO), gallium-zinc oxide (GZO), or aluminum-zinc oxide (AZO).

Embodiments may be realized by providing a manufacturing method of a thin film transistor array panel, including forming a gate electrode on a substrate; forming a semiconductor layer on the substrate; forming a gate insulating layer between the gate electrode and the semiconductor layer, the gate insulating layer including a first oxide insulating layer in contact with the gate electrode; forming a source electrode on the semiconductor layer and a drain electrode facing the source electrode; and forming a passivation layer covering the source electrode and the drain electrode, the passivation layer including a second oxide insulating layer in contact with the source electrode and the drain electrode, one or more of forming the gate insulating layer or forming the passivation layer including: forming a first sub-insulating layer covering the gate and the source electrode or the drain electrode; performing a plasma treatment on the first sub-insulating layer; and forming a second sub-insulating layer on a top surface of the first sub-insulating layer.

The plasma treatment may be nitride oxide plasma treatment, nitrogen plasma treatment, or hydrogen plasma treatment.

A hydrogen content in the first sub-insulating layer may be larger than a hydrogen content at an interface of the first sub-insulating layer with the second sub-insulating layer.

In forming the gate insulating layer, the first oxide insulating layer may be formed at a temperature of 260° C. to 350° C.

In forming the passivation layer, the first oxide insulating layer may be formed at a temperature of 150° C. to 250° C.

Forming the semiconductor layer and forming the source electrode and the drain electrode may be simultaneously performed using one mask.

### BRIEF DESCRIPTION OF THE DRAWINGS

Features will become apparent to those of skill in the art by describing in detail exemplary embodiments with reference to the attached drawings in which:

FIG. 1 illustrates a top plan view of a thin film transistor array panel according to an exemplary embodiment;

FIG. 2 illustrates a cross-sectional view taken along the line II-II of FIG. 1;

FIGS. 3 to 14 illustrate cross-sectional views of a manufacturing method of a thin film transistor array panel according to an exemplary embodiment; and

FIG. 15 illustrates a view of a hydrogen content of a passivation layer of a thin film transistor array panel according to the present exemplary embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. Like reference numerals refer to like elements throughout. In addition, in the specification, unless explicitly described to the contrary, the word “comprise” and variations such as “comprises” or “comprising”, will be understood to imply the inclusion of stated elements but not the exclusion of any other elements.

Further, the word “on” means positioning on or below the object portion, but does not essentially mean positioning on the upper side of the object portion based on a gravity direction. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present.

Hereinafter, a thin film transistor array panel according to an exemplary embodiment will be described in detail with reference to the drawings.

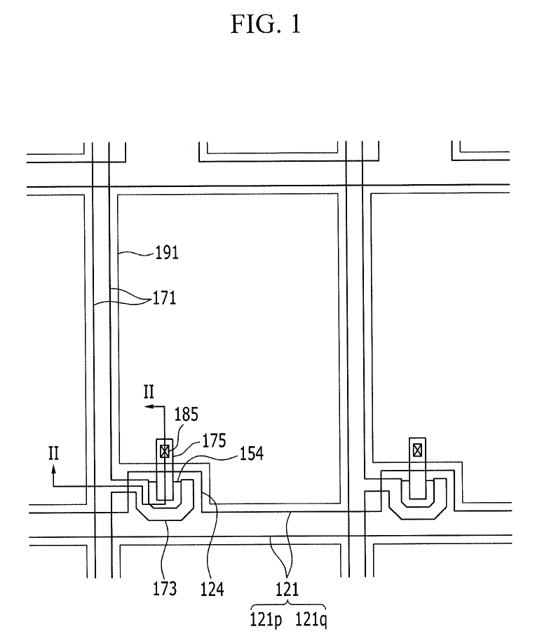

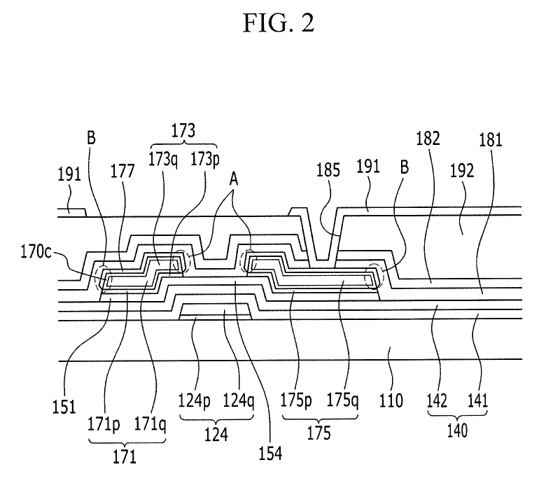

FIG. 1 illustrates a top plan view of a thin film transistor array panel according to an exemplary embodiment, and FIG. 2 illustrates a cross-sectional view taken along the line II-II of FIG. 1.

Referring to FIGS. 1 and 2, a thin film transistor array panel 100 according to the present exemplary embodiment may include a plurality of gate lines 121 which may be formed on an insulating substrate 110 formed of a transparent glass or plastic.

The gate lines 121 may transmit a gate signal and may mainly extend in a horizontal direction. Each gate line 121 may include a plurality of gate electrodes 124 which may protrude from the gate line 121.

The gate line 121 and the gate electrode 124 may have a dual layer structure which may be formed of first layers 121p and 124p and second layers 121q and 124q, respectively. The first layers 121p and 124p and the second layers 121q and 124q may be formed of an aluminum based metal such as aluminum (Al) and an aluminum alloy, a silver based metal such as silver (Ag) and a silver alloy, a copper based metal such as copper (Cu) and a copper alloy, a molybdenum based metal such as molybdenum (Mo) and a molybdenum alloy, chromium (Cr), titanium (Ti), tantalum (Ta), or manganese (Mn). For example, the first layers 121p and 124p may include titanium and the second layers 121q and 124q may include copper or a copper alloy.

The first layers 121p and 124p and the second layers 121q and 124q may be formed by combining layers having different physical properties. In the present exemplary embodiment, the gate line 121 and the gate electrode 124 may be formed to have a dual layer structure. In an embodiment, the gate line 121 and the gate electrode 124 may be formed to have a single layer structure or a triple layer structure.

A gate insulating layer 140 which may be formed of an insulating material, such as silicon oxide or silicon nitride, may be located on the gate line 121.

The gate insulating layer 140 may include a first nitride insulating layer 141 which may cover the gate electrode 124 and a first oxide insulating layer 142 which may be formed above the first nitride insulating layer 141.

The first nitride insulating layer 141 may be formed of silicon nitride (SiNₓ) and the first oxide insulating layer 142 may be formed of silicon oxide (SiOₓ).

The first oxide insulating layer 142 may be formed to have a varying distribution of hydrogen content with respect to a thickness direction of the first oxide insulating layer 142 and may include a plurality of sub-insulating layers 142a to 142n. In an embodiment, the first oxide insulating layer 142 may be formed to have discontinuous distribution of hydrogen content with respect to a thickness direction of the first oxide insulating layer 142 and may include a plurality of sub-insulating layers 142a to 142n.

The hydrogen content in the plurality of laminated sub-insulating layers 142a to 142n may be maintained to be, e.g., at, a predetermined level, and a hydrogen content at interfaces of the sub-insulating layers 142a to 142n may be smaller than the hydrogen content in the sub-insulating layers 142a to 142n.

Accordingly, the distribution of the hydrogen content of the first oxide insulating layer 142 with respect to the thickness direction may form a pattern in which the hydrogen content may be maintained to be, e.g., at, the predetermined level in the sub-insulating layers 142a to 142n and may be reduced at the interfaces of the sub-insulating layers 142a to 142n interface, for example, a pattern in which the hydrogen content may be repeatedly increased and reduced.

According to an exemplary embodiment, the first nitride insulating layer 141 may be formed of silicon oxynitride (SiON) and the first oxide insulating layer 142 may be formed of silicon oxide (SiOₓ).

In the present exemplary embodiment, the gate insulating layer 140 may be formed to have a dual layer structure. In an embodiment, the gate insulating layer 140 may be formed to have a single layer structure.

A semiconductor layer 151 may be formed on the gate insulating layer 140. The first oxide insulating layer 142 of the gate insulating layer 140 may be in contact with the semiconductor layer 151.

The semiconductor layer 151 may be formed of amorphous silicon, crystalline silicon, or oxide semiconductor. The semiconductor layer 151 may mainly extend in a vertical direction and may include a plurality of projections 154 which may extend towards the gate electrode 124.

When the semiconductor layer 151 is formed to be an oxide semiconductor, the semiconductor layer 151 may include one or more of zinc (Zn), indium (In), tin (Sn), gallium (Ga), or hafnium (Hf). For example, in the present exemplary embodiment, the semiconductor layer 151 may be indium-gallium-zinc oxide.

On the semiconductor layer 151 and the gate insulating layer 140, a data wiring layer which may include a plurality of data lines 171, a plurality of source electrodes 173 which may be connected to the data lines 171, and a plurality of drain electrodes 175 may be formed.

The data lines 171 may transmit a data signal and may mainly extend in a vertical direction to intersect the gate line 121. The source electrodes 173 may extend from the data lines 171 to overlap the gate electrode 124 and substantially have a U shape. However, structures of the source electrode 173 and the drain electrode 175 may be modified.

The drain electrode 175 may be separated from the data line 171 and may upwardly extend from a center of the U shape of the source electrode 173.

The data line 171, the source electrode 173, and the drain electrode 175 may have dual-layer structures of barrier layers 171p, 173p, and 175p, and main wiring layers 171q, 173q, and 175q, respectively. The barrier layers 171p, 173p, and 175p may be formed of metal oxide. For example, the barrier layers 171p, 173p, and 175p may be formed of indium-zinc oxide, gallium-zinc oxide, or aluminum-zinc oxide. The barrier layers 171p, 173p, and 175p may serve as a diffusion barrier layer which may prevent a material such as copper from diffusing onto the semiconductor layer 151.

The main wiring layers 171q, 173q, and 175q may include a first material and a second material which may be added to the first material. For example, the first material may be copper and the second material may include one or more of Mn, Mg, Al, Mo, W, Ti, Ga, In, Ni, La, Nd, Sn, Ag, Cr, Zr, Zn, or Fe. The main wiring layers 171q, 173q, and 175q may be a copper alloy. A content of the second material which may be added to the first material may be equal to or smaller than approximately 20% of an entire content, e.g., a total content of the first and second materials.

A diffusion metal layer 170c may be located on surfaces of the main wiring layers 171q, 173q, and 175q. In the present exemplary embodiment, the diffusion metal layer 170c may be formed to enclose the main wiring layers 171q, 173q, and 175q. The diffusion metal layer 170c may be formed by diffusing a material (second material) alloyed to the main wiring layers 171q, 173q, and 175q by heat treatment.

In the present exemplary embodiment, a metal oxide layer 177 may be formed along an exposed surface of the diffusion metal layer 170c. The metal oxide layer 177 may be formed by oxidizing the diffusion metal layer 170c which may be exposed to the outside. The diffusion metal layer 170c may be oxidized by nitride oxide plasma treatment.

In the present exemplary embodiment, the metal oxide layer 177 may cover the source electrode 173 and the drain electrode 175 while being in directly contact with the diffusion metal layer which may be located on the surfaces of the source electrode 173 and the drain electrode 175 and, for example, may cover exposed side walls A and B of the source electrode 173 and the drain electrode 175 and exposed upper surfaces of the source electrode 173 and the drain electrode 175. The metal oxide layer 177 may not be formed on a portion of the gate insulating layer 140 which does not overlap the source electrode 173 and the drain electrode 175 and on the channel region of the semiconductor layer 151.

Hereinafter, the exposed side walls A of the source electrode 173 and the drain electrode 175 which are adjacent to the channel region of the semiconductor layer 151 will be described in detail.

Referring to FIG. 2, there may be exposed portions which are not covered by the data line 171 and the drain electrode 175 between the source electrode 173 and the drain electrode 175, in the projection 154 of the semiconductor layer 151. Except for the exposed portion of the projection 154, the semiconductor layer 151 may have a substantially same plane pattern as the data line 171 and the drain electrode 175. For example, except for the exposed portion of the projection 154, a side wall of the semiconductor layer 151 may be aligned in the same manner as a side wall of the data line 171, a side wall of the source electrode 173, and a side wall of the drain electrode 175.

One gate electrode 124, one source electrode 173, and one drain electrode 175 may form one thin film transistor (TFT) together with the projection 154 of the semiconductor layer 151 and a channel region of the thin film transistor may be formed in the projection 154 between the source electrode 173 and the drain electrode 175.

The side walls of the source electrode 173 and the drain electrode 175 which are adjacent to the channel region may be exposed, the diffusion metal layer 170c may be located in the exposed side portions A of the source electrode 173 and the drain electrode 175, and the metal oxide layer 177 may cover the exposed side portions A of the source electrode 173 and the drain electrode 175.

A subsequent process of forming a passivation layer including silicon oxide may be performed in a state in which the side wall portions A of the source electrode 173 and the drain electrode 175 may be exposed without having a diffusion metal layer 170c and the metal oxide layer 177 or a heat treatment may be performed to allow the projection 154 of the semiconductor layer to have a channel characteristic, and the material, such as copper, which may be included in the main wiring layers 171q, 173q, and 175q may form porous oxide, and a thin film transistor characteristic may be degraded. In the present exemplary embodiment, the metal oxide layer 177 which may be formed by oxidizing the diffusion metal layer 170c and the diffusion metal layer 170c may prevent the material such as copper from being oxidized.

A passivation layer 180 may be formed on the source electrode 173, the drain electrode 175, and the metal oxide layer 177.

The passivation layer 180 according to the present exemplary embodiment may be formed of an inorganic insulator, such as silicon nitride or silicon oxide, an organic insulator, or an insulator having a low permittivity and may include a second oxide insulating layer 181 and a second nitride insulating layer 182.

The second oxide insulating layer 181 may be formed of silicon oxide (SiOₓ). The second oxide insulating layer 181 may cover the source electrode 173, the drain electrode 175, and the projection 154 while being in contact with the source electrode 173 and the drain electrode 175, and the projection 154 of the semiconductor layer 151 between the source electrode 173 and the drain electrode 175.

The second oxide insulating layer 181 may be formed to have a varying distribution of hydrogen content with respect to a thickness direction and may include a plurality of sub-insulating layers 181a to 181n. In an embodiment, the second oxide insulating layer 181 may be formed to have discontinuous distribution of hydrogen content with respect to a thickness direction and may include a plurality of sub-insulating layers 181a to 181n.

The hydrogen content in the plurality of laminated sub-insulating layers 181a to 181n may be maintained to be, e.g., at, a predetermined level, and a hydrogen content at interfaces of the sub-insulating layers 181a to 181n may be smaller than the hydrogen content in the sub-insulating layers 181a to 181n.

Accordingly, the distribution of the hydrogen content of the second oxide insulating layer 181 with respect to the thickness direction may form a pattern in which the hydrogen content may be maintained to be, e.g., at, the predetermined level in the sub-insulating layers 181a to 181n and may be reduced at the interfaces of the sub-insulating layers 181a to 181n, for example, a pattern in which the hydrogen content may be repeatedly increased and reduced.

The second nitride insulating layer 182 may be formed above the second oxide insulating layer 181 and may be formed of silicon nitride (SiNₓ).

A plurality of contact holes 185 which may pass through the second oxide insulating layer 181 and the second nitride insulating layer 182 may be formed in the passivation layer 180 to expose one end of the drain electrode 175.

An organic layer 192 may be formed on the passivation layer 180 and a pixel electrode 191 which may be physically and electrically connected to the drain electrode 175 through the contact hole 185 may be formed on a top surface of the organic layer 192 to be applied with a data voltage from the drain electrode 175.

Hereinafter, a process of forming the gate insulating layer 140 and the passivation layer 180 of the thin film transistor array panel according to the present exemplary embodiment will be described in detail.

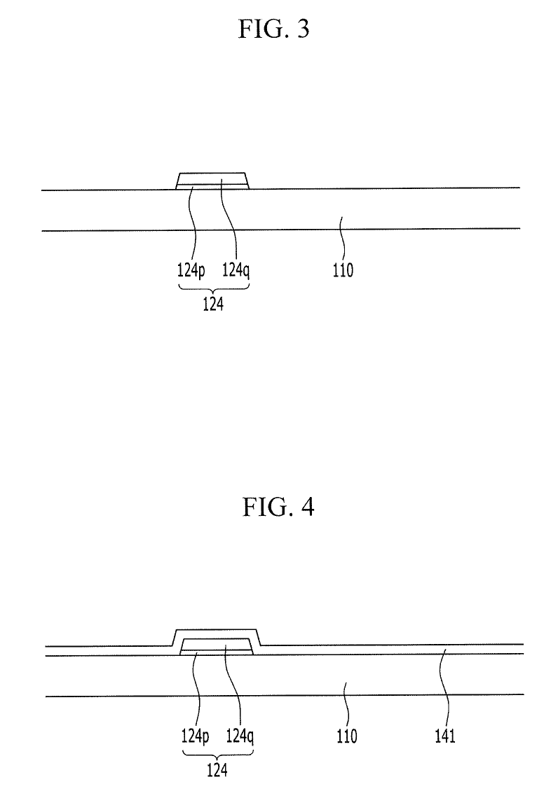

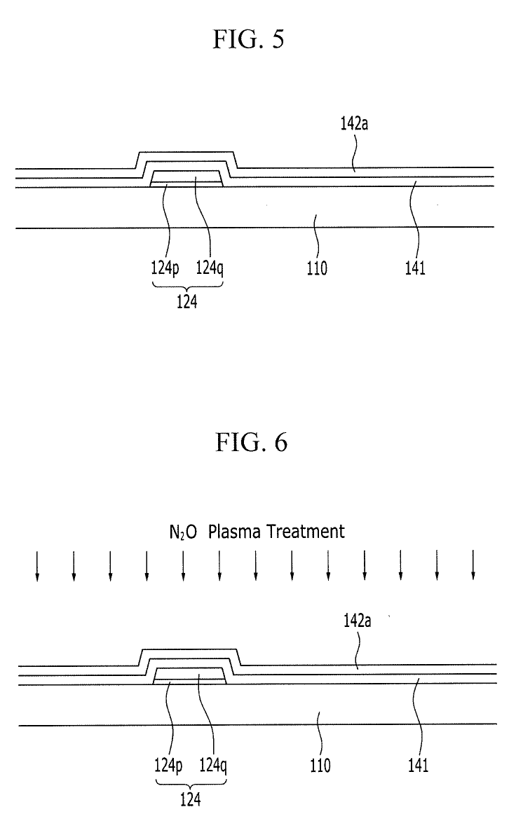

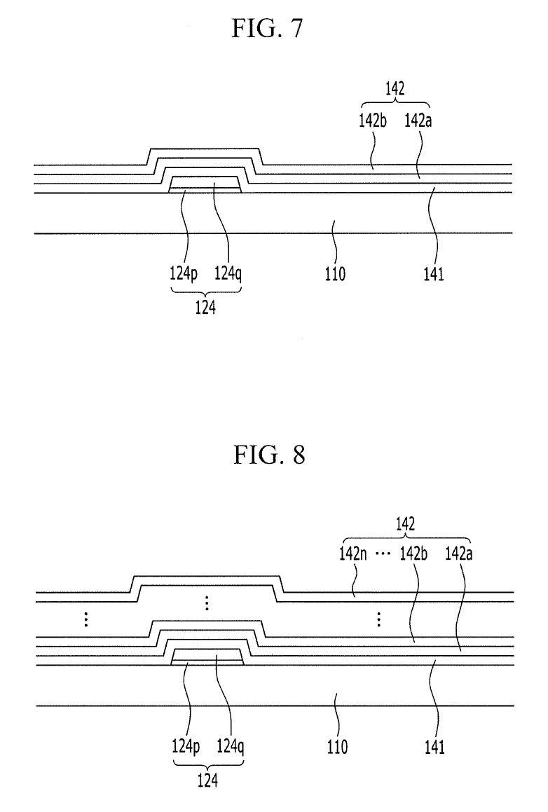

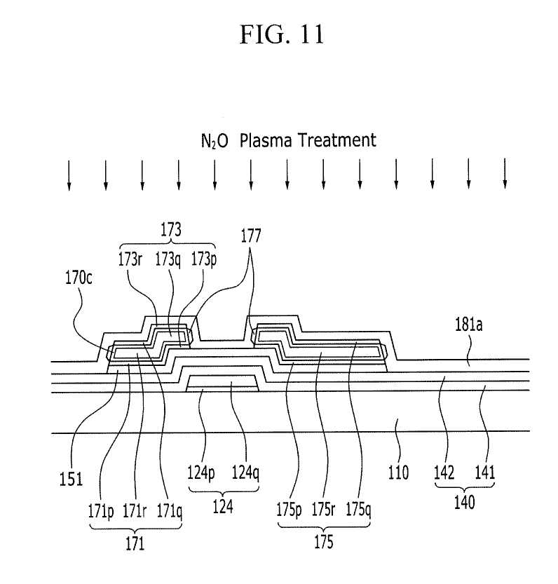

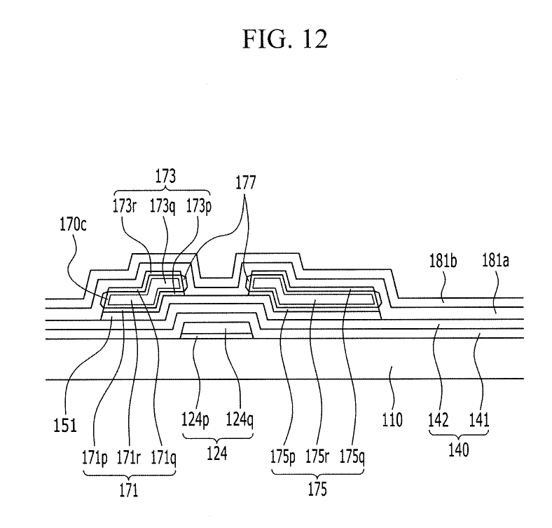

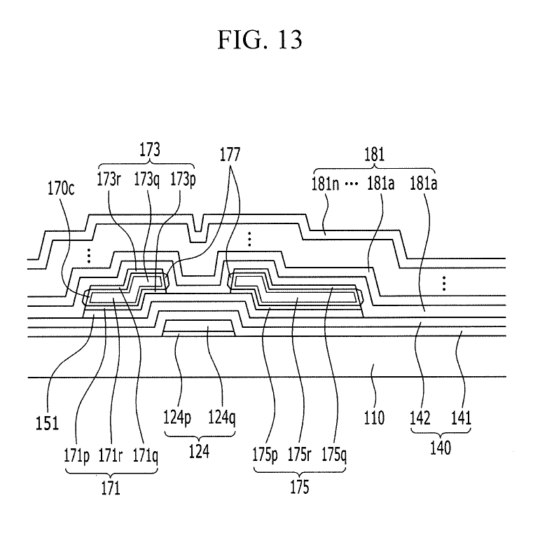

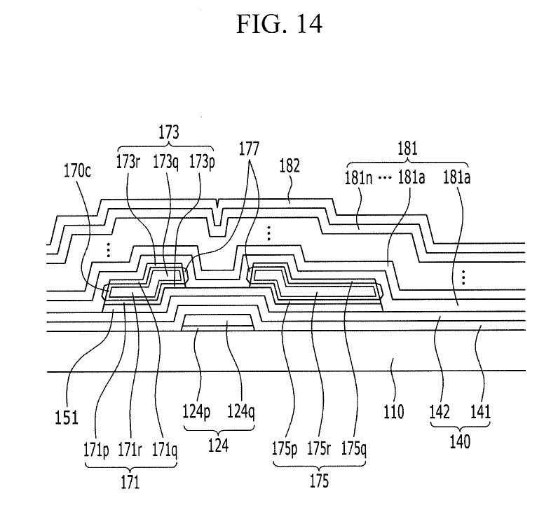

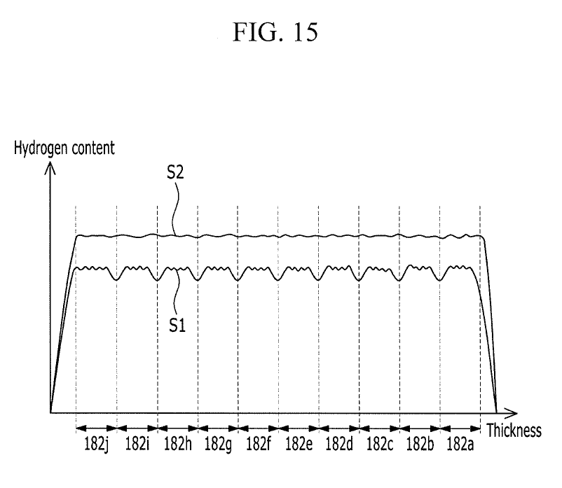

FIGS. 3 to 14 illustrate cross-sectional views of a manufacturing method of a thin film transistor array panel according to an exemplary embodiment.

First, a process of forming a gate insulating layer 140 of a thin film transistor array panel according to the exemplary embodiment will be described in detail with reference to FIGS. 3 to 8.

A dual layer may be formed by laminating one or more of a molybdenum based metal, such as molybdenum (Mo) or a molybdenum alloy, chromium (Cr), a chromium alloy, titanium (Ti), a titanium alloy, tantalum (Ta), a tantalum alloy, manganese (Mn), or a manganese alloy on an insulating substrate 110, which may be formed of transparent glass or plastic, and laminating an aluminum based metal, such as aluminum (Al) or an aluminum alloy, a silver based metal, such as silver (Ag) or a silver alloy, or a copper based metal, such as copper (Cu) or a copper alloy thereon, and then the dual layer may be patterned to form a gate line 121 including a gate electrode 124. For example, lower layers 121p and 124p may include titanium and upper layers 121q and 124q may include copper or a copper alloy.

For example, after forming the dual layer, a photosensitive film may be laminated and patterned and then the lower layers 121p and 124p and the upper layers 121q and 124q may be etched using the patterned photosensitive film as a mask. The etchant may etch the lower layers 121p and 124p and the upper layers 121q and 124q together.

Next, a first nitride insulating layer 141 among the gate insulating layers 141 may be laminated on the gate electrode 124.

Next, a first sub-insulating layer 142a of a first oxide insulating layer 142 may be laminated on the first nitride insulating layer 141. During the lamination of the first oxide insulating layer 142, hydrogen may flow into the first oxide insulating layer 142.

Next, in a state in which the first sub-insulating layer 142a may be laminated, a N₂O (nitrous oxide) plasma treatment may be performed on the first sub-insulating layer 142a.

The nitrous oxide (N₂O) plasma treatment may be performed on the first sub-insulating layer 142a, and hydrogen contained in the first sub-insulating layer 142a may react with nitrous oxide plasma to remove hydrogen from the first sub-insulating layer 142a.

Reaction of hydrogen and nitrous oxide plasma at an interface of the first sub-insulating layer 142a may be more actively performed than the reaction in the first sub-insulating layer 142a. Therefore, in a state in which the plasma treatment on the first sub-insulating layer 142a is completed, a hydrogen content of the interface of the first sub-insulating layer 142a may be smaller than a hydrogen content in the first sub-insulating layer 142a. The hydrogen content in the first sub-insulating layer 142 may be maintained to be, e.g., at, a predetermined level in a thickness direction.

The plasma treatment on the first sub-insulating layer 142a may be completed, and the second sub-insulating layer 142b may be laminated on the first sub-insulating layer 142a and nitrous oxide (N₂O) plasma treatment may be performed on a surface of the second sub-insulating layer 142b.

By the same method, lamination of the sub-insulating layers 142a to 142n to the n-th sub-insulating layer 142n and nitrous oxide (N₂O) plasma treatment on surfaces of the sub-insulating layers 142a to 142n may be alternately performed to form a first oxide insulating layer 142 having a predetermined thickness.

Thicknesses of the sub-insulating layers 142a to 142n may be 10 nm to 50 nm and a thickness of the sub-insulating layers 142a to 142n according to the present exemplary embodiment may be approximately 20 nm.

The first oxide insulating layer 142 may include five or more sub-insulating layers 142a to 142n. For example, in the present exemplary embodiment, the first oxide insulating layer 142 may include ten sub-insulating layers 142a to 142n, and the thickness of the first oxide insulating layer 142 may be 200 nm.

The first oxide insulating layer 142 may be laminated under a high temperature atmosphere of 260° C. to 350° C., for example, the first oxide insulating layer 142 according to the present exemplary embodiment may be laminated at approximately 280° C.

The lamination of the sub-insulating layers 142a to 142n and nitrous oxide (N₂O) plasma treatments which may be repeated several times may be performed in the same chamber.

In an embodiment, the plasma treatment of the first oxide insulating layer 142 according to the present exemplary embodiment may be performed using nitrous oxide (N₂O). In an embodiment, the plasma treatment may also be performed by, e.g., using, hydrogen (H₂), nitrogen (N₂), or argon (Ar) plasma treatment.

Hereinafter, a process of forming a passivation layer 180 of the thin film transistor array panel according to the present exemplary embodiment will be described in detail.

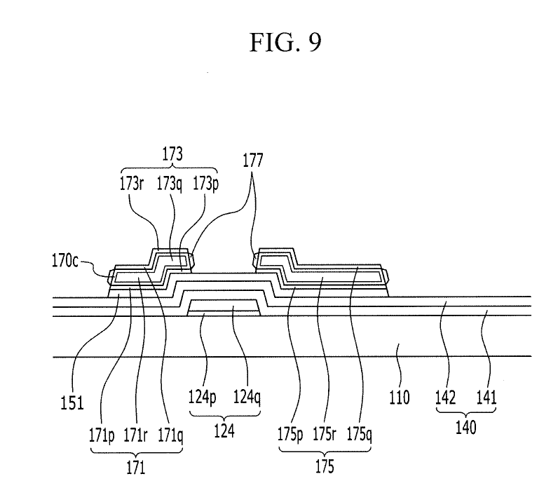

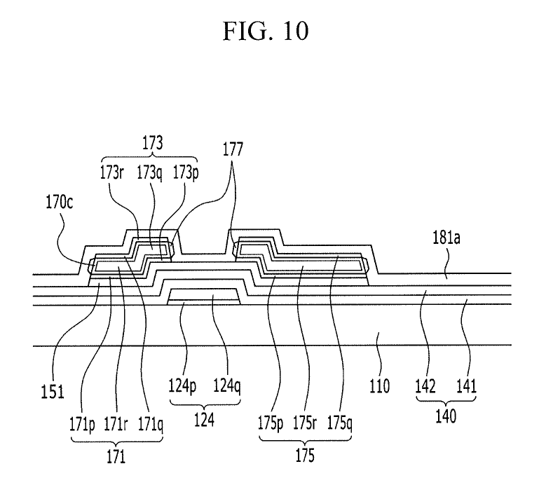

First, referring to FIG. 9, the first oxide insulating layer 142 may be formed, and then an oxide layer an metal oxide layer, and a metal layer 170q may be laminated above the gate insulating layer 140, the laminated oxide layer, metal oxide layer 170p, and metal layer 170q may be etched to form a semiconductor layer 151, a data line 171, a source electrode 173, and a drain electrode 175.

The semiconductor layer 151, the source electrode 173, and the drain electrode 175 may be simultaneously formed using one mask.

For example, a plurality of patterns may be sequentially formed on one mask and the semiconductor layer 151, the source electrode 173, and the drain electrode 175 may be simultaneously formed using the patterns.

The plurality of patterns which may be sequentially formed on one mask may be used, and semiconductor layers 151 and 154 which may have the substantially same plane pattern as barrier layers 171p, 173p, and 175p and main wiring layers 171q, 173q, and 175q of the data line 171, the source electrode 173, and the drain electrode 175 may be formed. For example, except for an exposed portion between the drain electrode 175 and the source electrode 173, side walls of the semiconductor layers 151 and 154 may be aligned in the substantially same manner as a side wall of the data line 171, a side wall of the source electrode 173, and a side wall of the drain electrode 175.

Next, referring to FIGS. 10 to 14, a first sub-insulating layer 181a of a second oxide insulating layer 181 of the passivation layer 180 may be formed on a projection of the semiconductor layer which may be exposed a metal oxide layer 177, a gate insulating layer 140 and a projection 154 of the semiconductor layer which may be exposed between the source electrode 173 and the drain electrode 175.

Next, in a state in which the first sub-insulating layer 181a may be laminated, a N₂O (nitrous oxide) plasma treatment may be performed on the first sub-insulating layer 181a.

Similar to the process of forming a first oxide insulating layer 142 of the gate insulating layer 140, the nitrous oxide (N₂O) plasma treatment may be performed on the first sub-insulating layer 181a, and hydrogen may be removed from the first sub-insulating layer 181a by reaction of hydrogen contained in the first sub-insulating layer 181a and nitrous oxide plasma.

Reaction of hydrogen and nitrous oxide plasma at an interface of the first sub-insulating layer 181a may be more actively performed than the reaction in the first sub-insulating layer 181a. Therefore, in a state in which the plasma treatment on the first sub-insulating layer 181a is completed, a hydrogen content of the interface of the first sub-insulating layer 181a may be smaller than a hydrogen content in the first sub-insulating layer 181a. The hydrogen content in the first sub-insulating layer 181a may be maintained to be, e.g., at, a predetermined level in a thickness direction.

The plasma treatment on the first sub-insulating layer 181a may be completed, and the second sub-insulating layer 181b may be laminated on the first sub-insulating layer 181a and nitrous oxide (N₂O) plasma treatment may be performed on a surface of the second sub-insulating layer 181b.

By the same method, deposition of the sub-insulating layers 181a to 181n to the n-th sub-insulating layer 142n and nitrous oxide (N₂O) plasma treatment on surfaces of the sub-insulating layers 181a to 181n may be alternately performed to form a second oxide insulating layer 181 having a predetermined thickness.

Thicknesses of the sub-insulating layers 181a to 181n are may be 10 nm to 50 nm and a thickness of the sub-insulating layers 181a to 181n according to the present exemplary embodiment may be approximately 20 nm.

The second oxide insulating layer 181 may include five or more sub-insulating layers 181a to 181n. For example, in the present exemplary embodiment, the second oxide insulating layer 181 may include ten sub-insulating layers 181a to 181n, and the thickness of the first oxide insulating layer 142 may be 200 nm.

The second oxide insulating layer 181 may be laminated under a low temperature atmosphere of 150° C. to 250° C., and the first oxide insulating layer 142 according to the present exemplary embodiment may be laminated at approximately 220° C.

For example, the, second oxide insulating layer 181 may be formed at a lower temperature atmosphere than the first oxide insulating layer 142, and a hydrogen content of the first oxide insulating layer 142 may be smaller than the hydrogen content of the second oxide insulating layer 181.

The lamination of the sub-insulating layers 181a to 181n and nitrous oxide (N₂O) plasma treatments which may be repeated several times may be performed in the same chamber.

The plasma treatment of the second oxide insulating layer 181 according to the present exemplary embodiment may be performed using nitrous oxide (N₂O). In an embodiment, the plasma treatment may also be performed by, e.g., using, hydrogen (H₂), nitrogen (N₂), or argon (Ar) plasma treatment.

The second oxide insulating layer 181 may be formed, and a second nitride insulating layer 182 may be formed on the second oxide insulating layer 181.

The passivation layer 180 in which the second oxide insulating layer 181 and the second nitride insulating layer 182 may be formed may be patterned to form a contact hole 185 through which a part of the drain electrode 175 may be exposed and an organic layer 192 and a pixel electrode 191 may be formed on the passivation layer 180, and the thin film transistor array panel as illustrated in FIG. 2 may be formed. The pixel electrode 191 may be formed to be physically connected to the drain electrode 175 through the contact hole 185.

In FIGS. 3 to 14, in order to explain a process of forming the first oxide insulating layer 142 of the gate insulating layer 140 including sub-insulating layers and the second oxide insulating layer 181 of the passivation layer 180, thicknesses of the first oxide insulating layer 142 and the second oxide insulating layer 181 may be exaggerated. The thicknesses of the first oxide insulating layer 142 and the second oxide insulating layer 181 may be similar to the thicknesses of the first nitride insulating layer 141 and the second nitride insulating layer 182, as illustrated in FIG. 1.

FIG. 15 illustrates a view of a hydrogen content of a passivation layer of a thin film transistor array panel according to the present exemplary embodiment.

Referring to FIG. 15, hydrogen content distribution S1 of the second oxide insulating layer 181 which may be formed in the passivation layer 180 of the thin film transistor array panel according to the present exemplary embodiment and hydrogen content distribution S2 of a comparative embodiment are illustrated.

Different from the second oxide insulating layer 181 according to the present exemplary embodiment, in the case of a second oxide insulating layer of a comparative embodiment, silicon oxide (SiOₓ) may be laminated once as much as, e.g., to, a thickness of the second oxide insulating layer and then plasma treatment may be performed.

In an entire section of the second oxide insulating layer 181, the hydrogen content distribution S1 of the second oxide insulating layer 181 may be formed to be lower than the hydrogen content distribution of the comparative embodiment.

The hydrogen content distribution S1 of the second oxide insulating layer 181 may be maintained to be, e.g., at, a predetermined level in the internal sections of the sub-insulating layers 181a to 181j and the hydrogen content at interface sections of the sub-insulating layers 181a to 181j may be smaller than the hydrogen content in the internal sections.

For example, different from the hydrogen content distribution S2 of the comparative embodiment which may be constant in the entire section, the hydrogen content distribution S1 of the second oxide insulating layer 181 may have a pattern in which the hydrogen content may be repeatedly increased and reduced.

The hydrogen content distribution of the first oxide insulating layer 142 formed in the gate insulating layer 140 of the thin film transistor array panel according to the present exemplary embodiment may be similar to the hydrogen content distribution of the second oxide insulating layer 181. However, since the first oxide insulating layer 142 may be formed at a higher temperature atmosphere than that of the second oxide insulating layer 181, the hydrogen content of the first oxide insulating layer 142 may be entirely lower than the hydrogen content of the second oxide insulating layer 181.

According to the suggested exemplary embodiment, during the process of forming an oxide insulating layer, the silicon oxide and the plasma treatment may be alternately laminated, and a hydrogen content of the oxide insulating layer may be reduced.

A thickness of the sub-insulating layer which may be included in the oxide insulating layer, a component of the plasma, or a plasma treatment time may be adjusted to adjust a hydrogen content in the oxide insulating layer to be a desired level.

By way of summation and review, a display device may use a thin film transistor (TFT) which may be a three terminal element as a switching element and may include signal lines such as a gate line which may transmit a scanning signal to control the thin film transistor and a data line which may transmit a signal to be applied to a pixel electrode.

A main wiring layer may be formed of a material such as copper or a copper alloy in order to reduce resistance of the signal line and a passivation layer may be provided to cover the main wiring layer in order to protect the main wiring layer from being oxidized. A large amount of hydrogen ions may be contained in the passivation layer, the hydrogen ions may act as a hole, and a performance of the thin film transistor which may be covered by the passivation layer may be deteriorated.

Provided is a thin film transistor array panel which may be formed to have an appropriate level of a hydrogen content in a passivation layer.

According to a display device according to an exemplary embodiment, during a process of forming an oxide insulating layer, a silicon oxide and a plasma treatment may be alternately laminated, and a hydrogen content of the oxide insulating layer may be reduced.

A thickness of a sub-insulating layer which may be included in the oxide insulating layer, a component of plasma, or a plasma treatment time may be adjusted to adjust a hydrogen content in the oxide insulating layer to be a desired level.

Example embodiments have been disclosed herein, and although specific terms are employed, they are used and are to be interpreted in a generic and descriptive sense only and not for purpose of limitation. In some instances, as would be apparent to one of skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A thin film transistor array panel, comprising:
a substrate;
a gate electrode on the substrate;
a semiconductor layer on the substrate;
a gate insulating layer between the gate electrode and the semiconductor layer, the gate insulating layer including a first oxide insulating layer in contact with the semiconductor layer;
a source electrode on the semiconductor layer;
a drain electrode facing the source electrode; and
a passivation layer covering the source electrode and the drain electrode, the passivation layer including a second oxide insulating layer in contact with the source electrode and the drain electrode,
at least one of the first oxide insulating layer and the second oxide insulating layer having a varying hydrogen content distribution in a thickness direction.

2. The thin film transistor array panel as claimed in claim 1, wherein a hydrogen content of at least one of the first oxide insulating layer and the second oxide insulating layer is repeatedly increased and reduced in the thickness direction.

3. The thin film transistor array panel as claimed in claim 2, wherein at least one of the first oxide insulating layer and the second oxide insulating layer includes a plurality of sub-insulating layers and a hydrogen content in each of the sub-insulating layers is larger than a hydrogen content at an interface of the sub-insulating layers.

4. The thin film transistor array panel as claimed in claim 3, wherein the hydrogen content in each of the sub-insulating layers is maintained at a predetermined level.

5. The thin film transistor array panel as claimed in claim 3, wherein a thickness of each of the sub-insulating layers is 10 nm to 50 nm.

6. The thin film transistor array panel as claimed in claim 3, wherein five or more sub-insulating layers are included in at least one of the first oxide insulating layer and the second oxide insulating layer.

7. The thin film transistor array panel as claimed in claim 1, wherein a hydrogen content of the first oxide insulating layer is smaller than a hydrogen content of the second oxide insulating layer.

8. The thin film transistor array panel as claimed in claim 1, further comprising a barrier layer below the source electrode and the drain electrode, wherein the barrier layer includes metal oxide.

9. The thin film transistor array panel as claimed in claim 8, wherein the barrier layer includes indium-zinc oxide (IZO), gallium-zinc oxide (GZO), or aluminum-zinc oxide (AZO).

10. A manufacturing method of a thin film transistor array panel, comprising:
forming a gate electrode on a substrate;
forming a semiconductor layer on the substrate;
forming a gate insulating layer between the gate electrode and the semiconductor layer, the gate insulating layer including a first oxide insulating layer in contact with the gate electrode;
forming a source electrode on the semiconductor layer and a drain electrode facing the source electrode; and
forming a passivation layer covering the source electrode and the drain electrode, the passivation layer including a second oxide insulating layer in contact with the source electrode and the drain electrode,
one or more of forming the gate insulating layer or forming the passivation layer including:
forming a first sub-insulating layer covering the gate and the source electrode or the drain electrode;
performing a plasma treatment on the first sub-insulating layer; and
forming a second sub-insulating layer on a top surface of the first sub-insulating layer.

11. The manufacturing method as claimed in claim 10, wherein the plasma treatment is nitride oxide plasma treatment, nitrogen plasma treatment, or hydrogen plasma treatment.

12. The manufacturing method as claimed in claim 10, wherein a hydrogen content in the first sub-insulating layer is larger than a hydrogen content at an interface of the first sub-insulating layer with the second sub-insulating layer.

13. The manufacturing method as claimed in claim 10, wherein, in forming the gate insulating layer, the first oxide insulating layer is formed at a temperature of 260° C. to 350° C.

14. The manufacturing method as claimed in claim 10, wherein, in forming the passivation layer, the first oxide insulating layer is formed at a temperature of 150° C. to 250° C.

15. The manufacturing method as claimed in claim 10, wherein forming the semiconductor layer and forming the source electrode and the drain electrode are simultaneously performed using one mask.
